(19) United States
(12) Patent Application Publication
(10) Pub. No.: US 2017/0221705 A1
(43) Pub. Date: Aug. 3, 2017

(54) COMPOSITE SUBSTRATE, SEMICONDUCTOR DEVICE, AND METHOD FOR MANUFACTURING THEREOF

(71) Applicant: KABUSHIKI KAISHA TOSHIBA, Tokyo (JP)

(72) Inventors: Mie MATSUO, Kamakura Kanagawa (JP); Atsuko KAWASAKI, Yokohama Kanagawa (JP)

(21) Appl. No.: 15/233,734

(22) Filed: Aug. 10, 2016

(30) Foreign Application Priority Data
Feb. 1, 2016 (JP) 2016-017409

(51) Int. Cl. H01L 21/02; H01L 21/762; H01L 23/373

(52) U.S. Cl. CPC H01L 21/02529; H01L 23/3738; H01L 21/02505; H01L 21/02494; H01L 21/02381; H01L 21/0262; H01L 21/02587; H01L 21/02488; H01L 21/76251; H01L 21/0254; H01L 33/007

(57) ABSTRACT

According to one embodiment, a semiconductor device is provided with a first single crystal layer, a polycrystalline layer provided on an entire surface of the first single crystal layer, and a second single crystal layer bonded to the polycrystalline layer. The coefficient of thermal expansion of the polycrystalline layer is greater than the coefficient of thermal expansion of the second single crystal layer, and is smaller than the coefficient of thermal expansion of a compound semiconductor layer which can be provided on the second single crystal layer using an intervening a buffer layer.

### CROSS-REFERENCE TO RELATED APPLICATION

This application is based upon and claims the benefit of priority from Japanese Patent Application No. 2016-017409, filed Feb. 1, 2016, the entire contents of which are incorporated herein by reference.

### FIELD

Embodiments described herein relate generally to a composite substrate, a semiconductor device, and a method for manufacturing thereof.

### BACKGROUND

A material having a wide band-gap, for example, gallium nitride (GaN) is used to form a light emitting diode (LED), a power device, and the like. A compound semiconductor layer containing gallium nitride is provided on, for example, a silicon substrate. In this case, if crystal defects are generated in the compound semiconductor layer due to a difference in coefficient of thermal expansion between the compound semiconductor layer and the silicon substrate, a crack or warping is likely to occur. As a result, there is a concern about a decrease in luminance or an increase in on resistance of the LED.

In this regard, a method to deal with the above issue is proposed. In this method, a thin single crystal silicon layer is bonded onto a polycrystalline substrate having a coefficient of thermal expansion which is approximate to that of gallium nitride rather than that of silicon, and a gallium nitride layer is provided on the single crystal silicon layer. According to this method, stress applied on the compound semiconductor layer is reduced, and thus the crack or the warping is less likely to occur.

However, when it comes to forming the compound semiconductor layer by bonding together a single crystal layer and a polycrystalline substrate, there is another issue as described below. For example, the polycrystalline substrate typically includes a ceramic sintered body, and thus it is not easy to perform a process of flattening its surface. For this reason, voids are generated at the time of bonding and thus the bonding is not sufficiently performed, which may cause manufacturing defects of the compound semiconductor layer.

In addition, typically, the polycrystalline substrate and the single crystal layer are bonded to each other using an intervening bonding layer, and thus the quality of the single crystal silicon layer is damaged depending on the material of the bonding layer, which also may cause manufacturing defects of the compound semiconductor layer.

### DESCRIPTION OF THE DRAWINGS

FIG. 1 is a sectional view illustrating a schematic configuration of a semiconductor device according to a first embodiment.

FIG. 2 is a sectional view illustrating a step of forming a polycrystalline layer.

FIG. 3 is a sectional view illustrating a step of forming a bonding layer.

FIG. 4 is a sectional view illustrating a step of implanting ions into a single crystal silicon substrate.

FIG. 5 is a sectional view illustrating a step of bonding the single crystal silicon substrate illustrated in FIG. 4.

FIG. 6 is a sectional view illustrating a step of separating the single crystal silicon substrate illustrated in FIG. 5.

FIG. 7 is a sectional view illustrating a step of bonding a single crystal silicon substrate in a second embodiment.

FIG. 8 is a sectional view illustrating a step of thinning the single crystal silicon substrate illustrated in FIG. 7.

FIG. 9 is a sectional view illustrating a schematic configuration of a semiconductor device according to a third embodiment.

FIG. 10 is a sectional view illustrating a schematic configuration of a semiconductor device according to a fourth embodiment.

FIG. 11 is a sectional view illustrating an example of a manufacturing step of a porous layer.

FIG. 12 is a sectional view illustrating a state before being separated by the porous layer.

FIG. 13 is a sectional view illustrating a state after being separated by the porous layer.

FIG. 14 is a sectional view illustrating a schematic configuration of a semiconductor device according to a fifth embodiment.

FIG. 15 is a sectional view illustrating a step of forming a bonding layer on the polycrystalline layer.

FIG. 16 is a sectional view illustrating a state before dissolving the bonding layer.

FIG. 17 is a sectional view illustrating a state after dissolving the bonding layer.

### DETAILED DESCRIPTION

One embodiment provides a composite substrate on which a compound semiconductor layer for a semiconductor device can be deposited or otherwise formed, a semiconductor device, and a method for manufacturing thereof which are capable of decreasing manufacturing defects of a compound semiconductor layer.

In general, according to one embodiment, a semiconductor device includes a first single crystal layer, a polycrystalline layer provided on an entire surface of the first single crystal layer, and a second single crystal layer bonded to the polycrystalline layer. The coefficient of thermal expansion of the polycrystalline layer is greater than the coefficient of thermal expansion of the second single crystal layer, and is smaller than a coefficient of thermal expansion of a compound semiconductor layer being provided on the second single crystal layer using and intervening buffer layer.

Hereinafter, the embodiments will be described with reference to the drawings. The present disclosure is not limited to the embodiments.

### First Embodiment

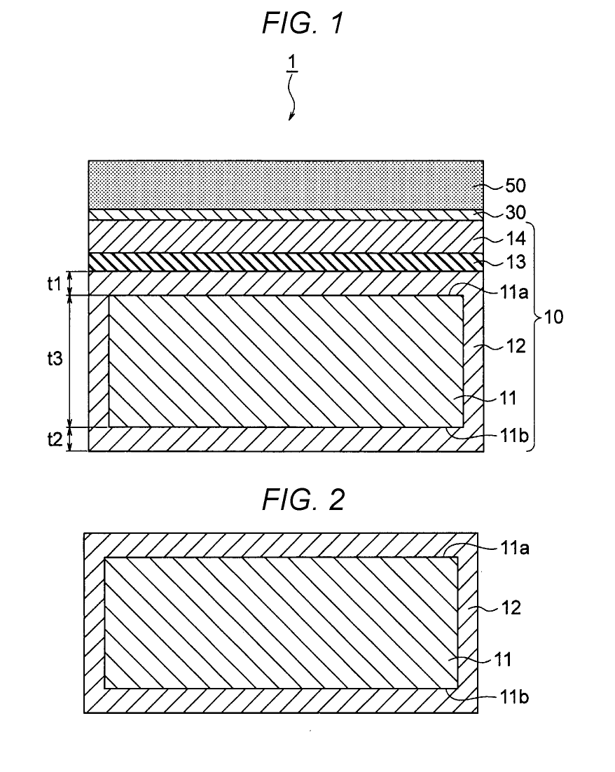

FIG. 1 is a sectional view illustrating a schematic configuration of a semiconductor device according to a first embodiment. As illustrated in FIG. 1, a semiconductor device 1 according to the first embodiment is provided with a composite substrate 10, a buffer layer 30 which is provided on the composite substrate 10, and a compound semiconductor layer 50 which is provided on the buffer layer 30. In addition, the composite substrate 10 includes a first single crystal layer 11, a polycrystalline layer 12, a bonding layer 13, and a second single crystal layer 14.

The first single crystal layer 11 includes a single crystal silicon or a single crystal sapphire. The entire surface of the first single crystal layer 11 is covered with the polycrystalline layer 12.

The coefficient of thermal expansion of the polycrystalline layer 12 is greater than the coefficient of thermal expansion of the second single crystal layer 14, and is smaller than the coefficient of thermal expansion of the compound semiconductor layer 50. In addition, the elastic modulus of the polycrystalline layer 12 is greater than the elastic modulus of the second single crystal layer 14.

Specifically, the polycrystalline layer 12 includes silicon carbide (SiC), aluminum nitride (AlN), or aluminum oxide (Al₂O₃).

In order to prevent the occurrence of warping of the first single crystal layer 11, the thickness of the polycrystalline layer 12 is preferably equal to or greater than 10 m. In addition, it is preferable that a thickness t1 of the polycrystalline layer 12 which covers an upper surface 11a is equal to a thickness t2 of the polycrystalline layer 12 which covers a lower surface 11b such that a residual stress of the polycrystalline layer 12 on the upper surface 11a of the first single crystal layer 11 is symmetrical to a residual stress of the polycrystalline layer 12 on the lower surface 11b of the first single crystal layer 11. Here, the expression that the thickness t1 and the thickness t2 equal to each other includes not only that the thickness t1 and the thickness t2 are equal to each other, but also that a difference therebetween is within a range in which the aforementioned residual stresses are symmetrical to each other.

In addition, in the first embodiment, each of the thickness t1 and the thickness t2 is smaller than a thickness t3 of the first single crystal layer 11. However, each of the thickness t1 and the thickness t2 may be equal to or greater than the thickness t3.

The bonding layer 13 is provided between the polycrystalline layer 12 and the second single crystal layer 14. The bonding layer 13 includes, for example, a silicon compound, polycrystalline silicon, or amorphous silicon. Examples of the silicon compound include silicon oxide (SiO₂), silicon oxynitride (SiON), silicon oxycarbonitride (SiOC), and silicon nitride (SiN), and the like. Particularly, if a material of the bonding layer 13 is polycrystalline silicon or amorphous silicon, the material is easily flattened by chemical mechanical polishing (CMP). For this reason, it is possible to improve the flatness of the bonding layer 13.

The second single crystal layer 14 is a seed layer for allowing the compound semiconductor layer 50 to be epitaxially grown thereon. The second single crystal layer 14 includes a single crystal silicon, a single crystal sapphire, a single crystal silicon carbide, or a single crystal gallium nitride. Particularly, if a material of the second single crystal layer 14 is single crystal silicon, it is preferable that the plane orientation of the single crystal silicon is (111). With this, it is possible to form a compound semiconductor layer 50 thereon having fewer crystal defects.

Hereinafter, a method for manufacturing the semiconductor device 1 according to the above-described exemplary embodiment will be described with reference to FIG. 2 to FIG. 6.

First, as illustrated in FIG. 2, the polycrystalline layer 12 is formed on the entire surface of the first single crystal layer 11. For example, when a material of the first single crystal layer 11 is single crystal silicon, and a material of the polycrystalline layer 12 is polycrystalline silicon carbide, the polycrystalline layer 12 is formed on the entire surface of the first single crystal layer 11 using a chemical vapor deposition (CVD) method.

Typically, in a polycrystalline silicon carbide formed using the CVD method, the crystalline structure thereof changes due to a temperature or other conditions of film formation, and thus a stress is generated in some cases. However, if the polycrystalline silicon carbide is formed on both surfaces of the single crystal silicon, it is possible to minimize the occurrence of the warping of polycrystalline silicon carbide. Therefore, it is preferable that the polycrystalline silicon carbide is formed on both surfaces of the single crystal silicon at the same time. In other words, it is preferable that the polycrystalline layer 12 is formed on the upper surface 11a of the first single crystal layer 11 and on the lower surface 11b of the first single crystal layer 11 at the same time.

In addition, in order to improve the flatness of the polycrystalline layer 12, it is preferable that the surface of the polycrystalline layer 12 is in a mirror state. Specifically, it is preferable that the surface of the polycrystalline layer 12 is polished such that the surface roughness thereof is equal to or less than 0.1 μm.

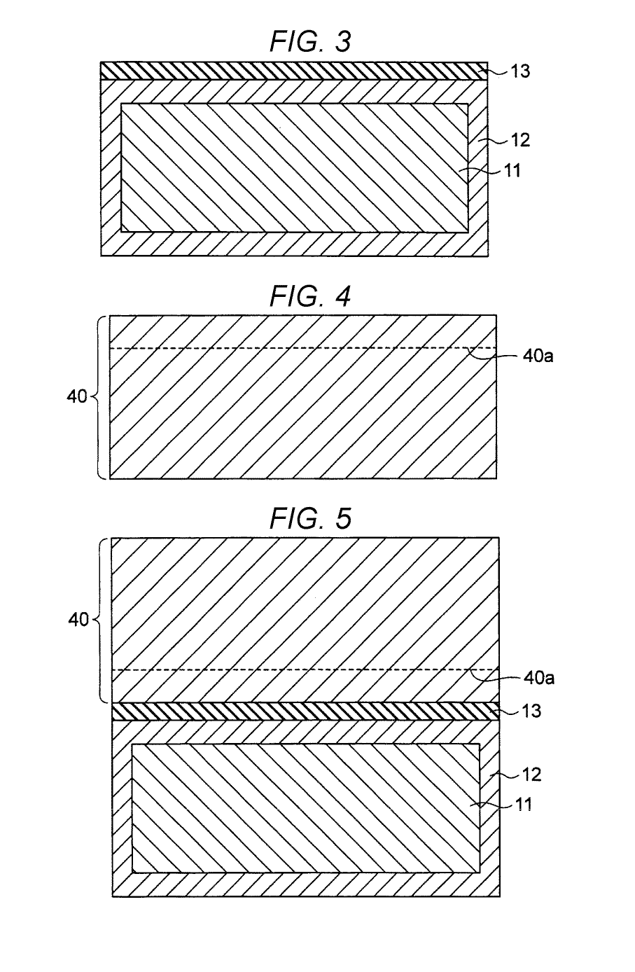

Next, as illustrated in FIG. 3, the bonding layer 13 is formed on an upper surface of the polycrystalline layer 12. For example, if the material of the bonding layer 13 is a silicon oxide film, the bonding layer 13 is formed on the upper surface of the polycrystalline layer 12 using the CVD method. In this case, it is preferable that the silicon oxide film is formed at a high temperature or the silicon oxide film is heated after being formed. With this, it is possible to prevent H₂O and gas from outgassing from the inside of the silicon oxide film during the formation of the compound semiconductor layer 50. Further, in order to obtain the suitable flatness in which an upper surface of the bonding layer 13 is bonded to the second single crystal layer 14, it is preferable that the upper surface of the bonding layer 13 is subjected to CMP.

Next, hydrogen ions are implanted into a single crystal silicon substrate 40. As a result, as illustrated in FIG. 4, an ion implantation region 40a is formed in the single crystal silicon substrate 40. The ion implantation region 40a forms a mechanically weakened area of the silicon substrate 40. Meanwhile, in addition to hydrogen ions, the ion which is implanted into the single crystal silicon substrate 40 may be a nitrogen ion, an oxygen ion, a neon ion, an argon ion, or a combination of thereof.

Subsequently, as illustrated in FIG. 5, the single crystal silicon substrate 40 is bonded to the bonding layer 13. In the first embodiment, the single crystal silicon substrate 40 is bonded to the bonding layer 13 using Fusion bonding. Specifically, the surface of the single crystal silicon substrate 40 and the surface of the bonding layer 13 are processed by using plasma which contains nitrogen (N₂), oxygen (O₂), or the like. Thereafter, both surfaces are washed by water. Then, both of the surfaces are bonded by hydrogen bonding and thus the single crystal silicon substrate 40 is bonded to the bonding layer 13 in the nitrogen (N₂), oxygen (O₂), or the like environment. After that, in order to firmly bond the single crystal silicon substrate 40 and the bonding layer 13, it is preferable that a heat treatment is performed at a temperature in a range of 150° C. to 300° C. for 2 hours to 15 hours.

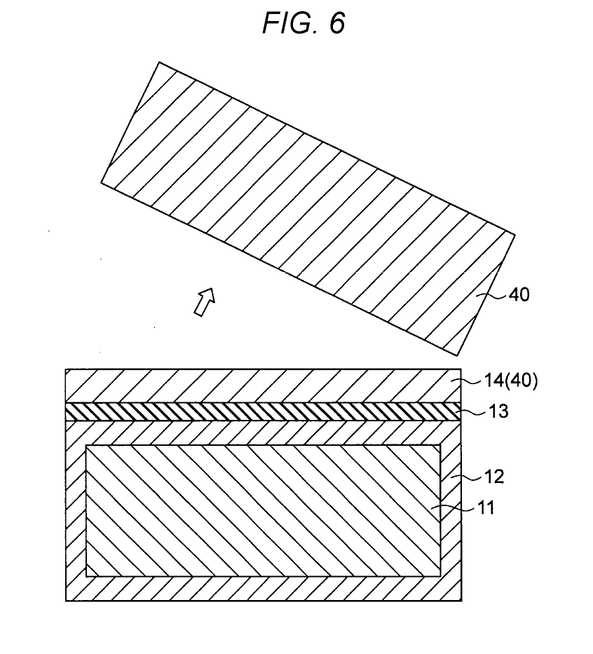

Further, a structure as illustrated in FIG. 5, that is, the structure including the first single crystal layer 11, the polycrystalline layer 12, the bonding layer 13, and the single crystal silicon substrate 40 is heated to approximately 500° C. As a result, the single crystal silicon substrate 40 is separated in the ion implantation region 40a (mechanically weakened area) as illustrated in FIG. 6. In this case, a portion which remains on the bonding layer 13 corresponds to the second single crystal layer 14. The surface of the second single crystal layer 14 is then flattened such as by polishing.

At last, returning to FIG. 1, the buffer layer 30 is formed on the second single crystal layer 14, and the compound semiconductor layer 50 is epitaxially grown and is thus formed on the buffer layer 30.

If the semiconductor device 1 is a field effect transistor, the compound semiconductor layer 50 is a stacked body which includes a gallium nitride (GaN) layer and an aluminum gallium nitride (AlGaN) layer having a wider band gap than that of the gallium nitride (GaN) layer. In addition, if the semiconductor device 1 is an LED, the compound semiconductor layer 50 is a stacked body which includes the gallium nitride (GaN) layer and a light emitting layer.

Meanwhile, in a step illustrated in FIG. 3, if polysilicon or amorphous silicon is used for the bonding layer 13, the bonding layer 13 is formed by using the CVD method, and the upper surface of the bonding layer 13 is flattened through the CMP. In this case, the second single crystal layer 14 is coupled to the bonding layer 13 by covalent bonding. According to this structure, if the material of the bonding layer 13 is a conductive material, it is possible to use the bonding layer 13 as a conductive layer. In addition, the thermal conductivity of the conductive material is higher than the thermal conductivity of an insulating film such as a silicon oxide film. For this reason, if the material of the bonding layer 13 is a conductive material, it is possible for the compound semiconductor layer 50 to be uniformly epitaxially grown.

In addition, if polysilicon or amorphous silicon is used for the bonding layer 13, in a step illustrated in FIG. 5, an oxide or an organic matter which is attached on the surface of the single crystal silicon substrate 40 is removed by the argon ion, plasma, or the like in a vacuum, and thereafter, the single crystal silicon substrate 40 is bonded to the bonding layer 13 in a vacuum state.

According to the semiconductor device 1 in the first embodiment described above, the polycrystalline layer 12 is provided on the entire surface of the first single crystal layer 11, and the polycrystalline layer 12 and the second single crystal layer 14 are bonded to each other by the bonding layer 13. In other words, in the first embodiment, the second single crystal layer 14 for forming the compound semiconductor layer 50 is not bonded to a sintered substrate which is not easily processed, but bonded to the film-shaped polycrystalline layer 12 which easily obtains the desired flatness. For this reason, when the polycrystalline layer 12 and the second single crystal layer 14 are bonded to each other, voids are hardly generated, and thus it is possible to decrease manufacturing defects of the compound semiconductor layer 50 which is formed on the second single crystal layer 14.

### Second Embodiment

The second embodiment will be described. In the second embodiment, the description will focus on differences from the first embodiment as described above. In the second embodiment, the method for manufacturing the composite substrate 10 is different from that of the first embodiment. Hereinafter, the method for manufacturing the composite substrate according to the second embodiment will be described.

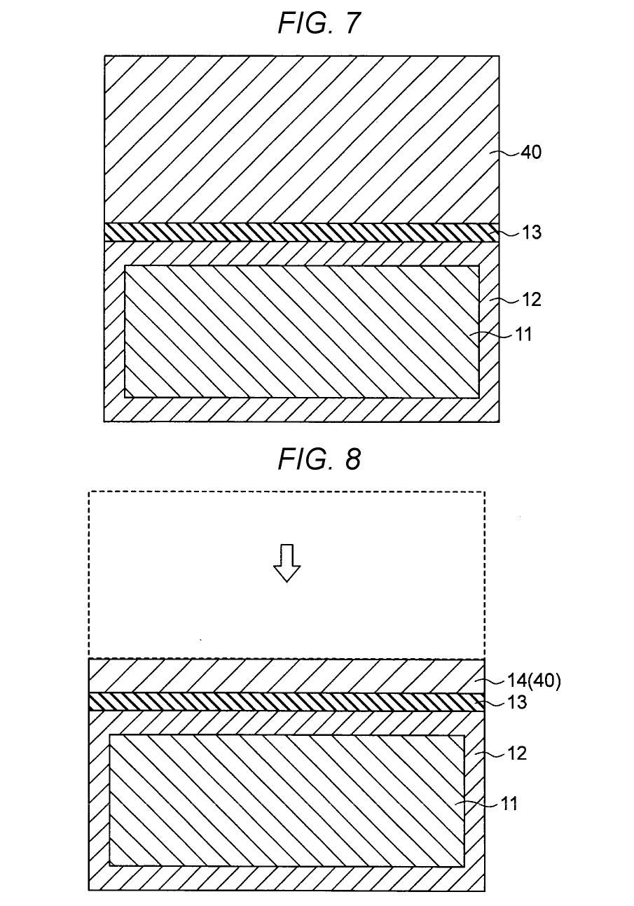

In the second embodiment, FIG. 7 is a sectional view illustrating a step of bonding the single crystal silicon substrate. As illustrated in FIG. 7, the step until the single crystal silicon substrate 40 is bonded on the bonding layer 13 is the same as that in the first embodiment. However, in the second embodiment, the ions are not implanted into the single crystal silicon substrate 40.

FIG. 8 is a sectional view illustrating a step of thinning the single crystal silicon substrate 40 illustrated in FIG. 7. As illustrated in FIG. 8, in the second embodiment, the single crystal silicon substrate 40 is thinned by grinding and CMP, or by wet etching. This thin portion of the substrate 40 corresponds to the second single crystal layer 14. The second single crystal layer 14 is heated so as to strengthen the bonding.

After forming the second single crystal layer 14 as described above, similar to the first embodiment, the buffer layer 30 is formed on the second single crystal layer 14, and the compound semiconductor layer 50 is epitaxially grown and is formed on the buffer layer 30.

According to the second embodiment as described above, a step of implanting ions is not necessary when forming the second single crystal layer 14. Thus, as compared with the first embodiment, it is possible to simplify the manufacturing process, thereby reducing manufacturing cost.

### Third Embodiment

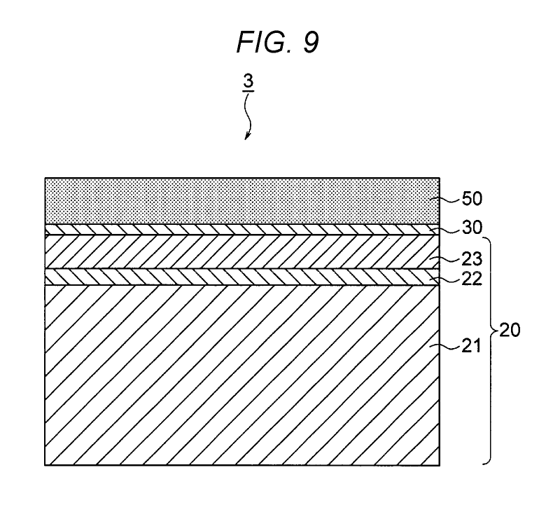

FIG. 9 is a sectional view illustrating a schematic configuration of a semiconductor device according to the third embodiment. As illustrated in FIG. 9, the semiconductor device 3 according to the third embodiment is provided with a composite substrate 20, the buffer layer 30 provided on the composite substrate 20, and the compound semiconductor layer 50 which is provided on the buffer layer 30. Since the buffer layer 30 and the compound semiconductor layer 50 are the same as those in the first embodiment as described above, the descriptions thereof will be omitted. The composite substrate 20 includes a polycrystalline layer 21, a bonding layer 22, and a single crystal layer 23.

The coefficient of thermal expansion of the polycrystalline layer 21 is greater than the coefficient of thermal expansion of the single crystal layer 23, and is smaller than the coefficient of thermal expansion of the compound semiconductor layer 50. Specifically, the polycrystalline layer 21 includes silicon carbide or aluminum nitride.

If a material of the polycrystalline layer 21 is silicon carbide, the polycrystalline layer 21 is manufactured by using a polycrystalline silicon carbide wafer. A method for manufacturing the polycrystalline silicon carbide wafer may be a high temperature sintering method, or the CVD method.

On the other hand, if the material of the polycrystalline layer 21 is aluminum nitride, the aluminum forms the impurity level in silicon, and thus it is not preferable that exposed aluminum is used in the semiconductor process. Here, when the polycrystalline layer 21 is manufactured, it is preferable that the entire aluminum nitride substrate is covered with silicon nitride or silicon oxide, or both of them.

The bonding layer 22 is provided between the polycrystalline layer 21 and the single crystal layer 23. A chemical element of the bonding layer 22 is the same as a chemical element of the single crystal layer 23. If the single crystal layer 23 includes single crystal silicon, the bonding layer 22 includes polycrystalline silicon.

The single crystal layer 23 is a seed layer for allowing the compound semiconductor layer 50 to be epitaxially grown. If the single crystal layer 23 includes single crystal silicon, it is preferable that the plane orientation is (111). With this, it is possible to form the compound semiconductor layer 50 having less crystal defects.

As described in the first embodiment, the single crystal layer 23 can be formed by separating the single crystal silicon substrate at a high temperature after the single crystal silicon layer into which ions are implanted is bonded to the bonding layer 22. In addition, as described in the second embodiment, the single crystal layer 23 can be formed by thinning the single crystal silicon substrate after the single crystal silicon substrate into which ions are not implanted is bonded to the bonding layer 22.

After the single crystal layer 23 is formed as described above, similar to the above-described first embodiment, the buffer layer 30 is formed on the second single crystal layer 14, and the compound semiconductor layer 50 is epitaxially grown thereon.

In the third embodiment as described above, if the chemical element of the bonding layer 22 is different from the chemical element of the single crystal layer 23, strain may occur on the single crystal layer 23 when bonding the bonding layer 22 to the single crystal layer 23. In this case, this strain is likely to cause manufacturing defects of the compound semiconductor layer 50 which is formed on the single crystal layer 23.

However, in the third embodiment, the chemical element of the bonding layer 22 is the same as the chemical element of the single crystal layer 23. Therefore, the aforementioned strain is less likely to occur on the single crystal layer 23. Accordingly, it is possible to decrease the manufacturing defects of the compound semiconductor layer 50 which is formed on the single crystal layer 23.

If the single crystal layer 23 is single crystal silicon, and the bonding layer 22 is polycrystalline silicon, other chemical elements other than are not present between the single crystal layer 23 and the bonding layer 22.

### Fourth Embodiment

The fourth embodiment will be described. In the fourth embodiment, the description will note differences in the embodiment compared to the above-described first to third embodiments.

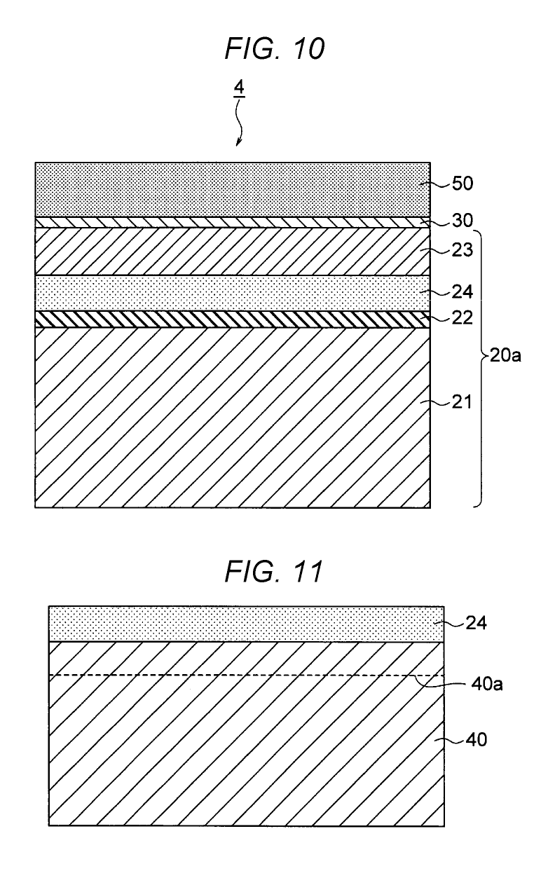

FIG. 10 is a sectional view illustrating a schematic configuration of a semiconductor device according to the fourth embodiment. As illustrated in FIG. 10, a semiconductor device 4 according to the fourth embodiment is different from the semiconductor device 3 according to the third embodiment in that semiconductor device 4 is provided with a composite substrate 20a. The composite substrate 20a is different from the composite substrate 20 according to the third embodiment in that the composite substrate 20a is further provided with a porous layer 24. The porous layer 24 is provided between the bonding layer 22 and the single crystal layer 23.

FIG. 11 is a sectional view illustrating an example of a manufacturing step of the porous layer 24. Here, both of the material of the single crystal layer 23 and the material of the porous layer 24 are silicon.

As illustrated in FIG. 11, the porous layer 24 is formed on a single crystal silicon substrate 40. The porous layer 24 may be formed by anodization or catalyst etching of the surface of the single crystal silicon substrate 40. In the method illustrated in FIG. 11, before the porous layer 24 is formed, an ion implanted region 40a is formed on the single crystal silicon substrate 40 similar to the case in the first embodiment.

The porous layer 24 which is formed on the single crystal silicon substrate 40 is bonded to the bonding layer 22. Thereafter, by separating the single crystal silicon substrate 40 at a high temperature, the single crystal layer 23 is formed on the porous layer 24.

Meanwhile, the porous layer 24 may be formed on the single crystal silicon substrate 40 on which the ion implanted region 40a is not provided. In this case, the single crystal silicon substrate 40 is thinned by being polished, and thereby the single crystal layer 23 is formed.

After the single crystal layer 23 is formed as described above, similar to the above-described first embodiment, the buffer layer 30 is formed on the second single crystal layer 14, and the compound semiconductor layer 50 is epitaxially grown, and is formed on the buffer layer 30.

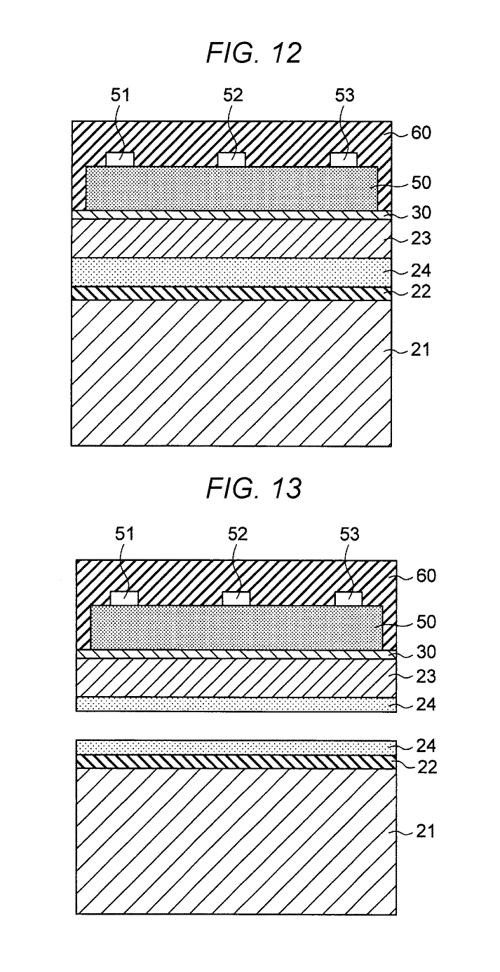

The compound semiconductor layer 50 is divided into individual devices through reactive ion etching (RIE) or wet etching. If the device is a field effect transistor, for example, a drain electrode 51, a gate electrode 52, and a source electrode 53 are formed on the compound semiconductor layer 50 as illustrated in FIG. 12.

Further, the surface of the compound semiconductor layer 50 and the surface of each of electrodes 51 to 53 are covered with the surface protective layer 60 as illustrated in FIG. 12. The surface protective layer 60 includes, for example, resist. Thereafter, as illustrated in FIG. 13, the field effect transistor portion and the polycrystalline layer 21 are separated from each other when a water jet or a blade comes into contact with the porous layer 24. In addition, in the field effect transistor portion, the surface protective layer 60 is peeled off therefrom. Meanwhile, the polycrystalline layer 21 is reused.

In the fourth embodiment as described above, the porous layer 24 is provided between the bonding layer 22 and the single crystal layer 23, and the polycrystalline layer 21 is separated from the device such as the field effect transistor at the porous layer 24. With this configuration, the polycrystalline layer 21 can be reused, and thus it is possible to obtain excellent effects in terms of economic and environmental aspects.

### Fifth Embodiment

The fifth embodiment will be described. In the fifth embodiment, the description will focus on differences from the above-described first to fourth embodiments.

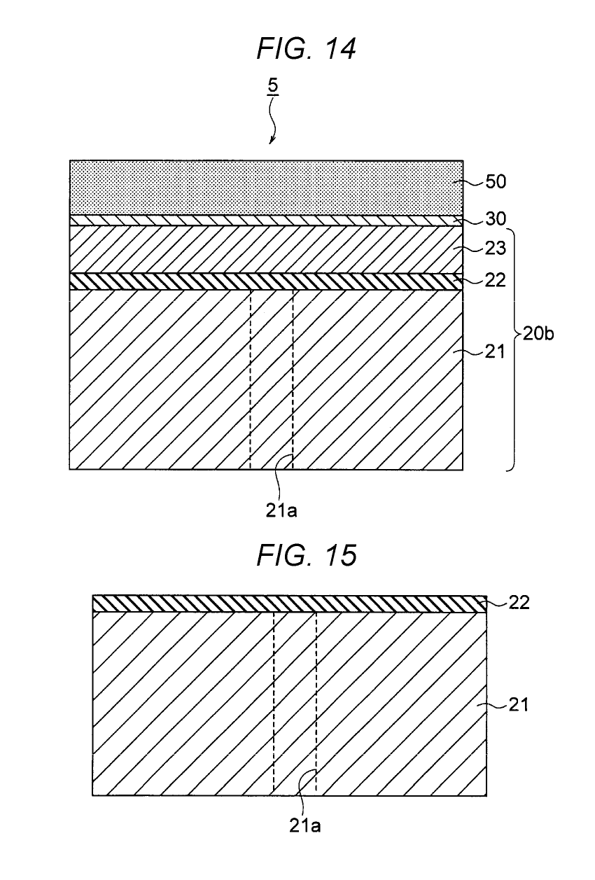

FIG. 14 is a sectional view illustrating a schematic configuration of a semiconductor device according to the fifth embodiment. As illustrated in FIG. 14, a semiconductor device 5 according to the fifth embodiment is different from the semiconductor device 3 according to the third embodiment in that the semiconductor device 5 is provided with the composite substrate 20b. On the composite substrate 20b, one or more through holes 21a which pass through the polycrystalline layer 21 are formed.

FIG. 15 is a sectional view illustrating a step of forming the bonding layer 22 on the polycrystalline layer 21. As illustrated in FIG. 15, in the fifth embodiment, the bonding layer 22 is formed on the polycrystalline layer 21 in which the through hole 21a is formed in advance. Since the step until the compound semiconductor layer 50 is formed is the same as that in the first embodiment or the second embodiment, the description thereof will be omitted.

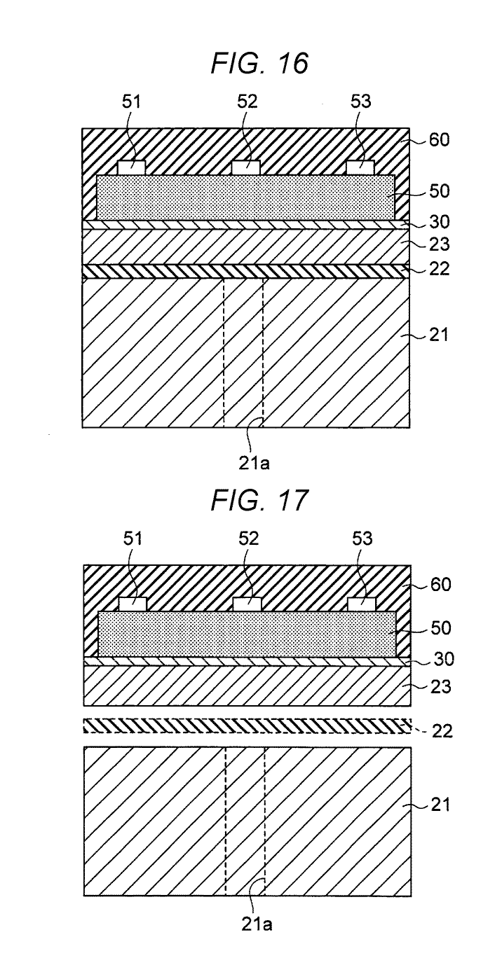

Similar to the fourth embodiment, the compound semiconductor layer 50 is divided into individual devices by RIE or wet etching. If the device is a field effect transistor, for example, the drain electrode 51, the gate electrode 52, and the source electrode 53 are formed on the compound semiconductor layer 50 as illustrated in FIG. 16.

Further, the surface of the compound semiconductor layer 50 and the surface of each of electrodes 51 to 53 are covered with the surface protective layer 60 as illustrated in FIG. 16. Thereafter, the semiconductor device is immersed into a liquid which is capable of dissolving the bonding layer 22. This liquid flows into the bonding layer 22 via the through hole 21a which is formed on the polycrystalline layer 21. If the bonding layer 22 is silicon oxide, it is possible to use, for example, a hydrofluoric acid (HF) as the aforementioned liquid.

FIG. 17 is a sectional view illustrating a state after dissolving the bonding layer 22. As illustrated in FIG. 17, the field effect transistor portion, and the polycrystalline layer 21 are separated from each other by dissolving the bonding layer 22. In the field effect transistor portion, the surface protective layer 60 is peeled off. Meanwhile, the polycrystalline layer 21 is reused.

In the fifth embodiment as described above, the through hole 21a is provided in the polycrystalline layer 21, and a dissolving liquid for the bonding layer 22 flows into the bonding layer 22 via the through hole 21a. With this configuration, it is easily possible to dissolve the bonding layer 22. Further, the polycrystalline layer 21 can be reused after dissolving the bonding layer 22, and thus it is possible to obtain excellent effects in terms of economic and environmental aspects.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first single crystal layer;
a polycrystalline layer provided on an entire surface of the first single crystal layer;
a second single crystal layer bonded to the polycrystalline layer; and
a compound semiconductor layer disposed on the second single crystal layer with a buffer layer therebetween,
wherein the coefficient of thermal expansion of the polycrystalline layer is greater than the coefficient of thermal expansion of the second single crystal layer, and is smaller than the coefficient of thermal expansion of the compound semiconductor layer.

2. The semiconductor device according to claim 1, wherein the first single crystal layer comprises single crystal silicon or single crystal sapphire.

3. The semiconductor device according to claim 1, wherein the second single crystal layer comprises single crystal silicon, single crystal sapphire, single crystal silicon carbide, or single crystal gallium nitride.

4. The semiconductor device according to claim 1, wherein the polycrystalline layer and the second single crystal layer are bonded together by a bonding layer comprising one of a silicon compound, polycrystalline silicon, or amorphous silicon.

5. The semiconductor device according to claim 1, wherein the thickness of the polycrystalline layer covering the upper surface of the first single crystal layer is equal to the thickness of the polycrystalline layer covering the lower surface of the first single crystal layer.

6. The semiconductor device according to claim 1, wherein the polycrystalline layer surrounds the first single crystal layer.

7. The semiconductor device of claim 1, wherein
the first single crystal layer comprises single crystal silicon or single crystal sapphire, and
the second single crystal layer comprises single crystal silicon, single crystal sapphire, single crystal silicon carbide, or single crystal gallium nitride.

8. A method for manufacturing a semiconductor device, comprising:
providing a polycrystalline layer on an entire surface of a first single crystal layer;
bonding a second single crystal layer onto the polycrystalline layer;
forming a buffer layer on the second single crystal layer; and
forming a compound semiconductor layer on the buffer layer,
wherein a coefficient of thermal expansion of the polycrystalline layer is greater than a coefficient of thermal expansion of the second single crystal layer, and is smaller than the coefficient of thermal expansion of the compound semiconductor layer.

9. The method of claim 8, wherein
the first single crystal layer comprises a first surface, and second surface facing a way from the first surface, and a side surface, and
providing the polycrystalline layer comprises depositing a polycrystalline material on the entirety of the first, second and side surfaces.

10. The method of claim 8, wherein
the first single crystal layer comprises single crystal silicon or single crystal sapphire, and
the second single crystal layer comprises single crystal silicon, single crystal sapphire, single crystal silicon carbide, or single crystal gallium nitride.

11. The method of claim 8, wherein
the first single crystal layer comprises a first surface, and second surface facing a way from the first surface, and a side surface, and
providing the polycrystalline layer on an entire surface of a first single crystal layer comprises depositing a polycrystalline on the entirety of the first, second and side surfaces.

12. A semiconductor device, comprising:
a polycrystalline layer;
a single crystal layer bonded to the polycrystalline layer;
a bonding layer comprising a polycrystalline material of an element which is the same as an element of the single crystal layer, the bonding layer bonding together the polycrystalline layer and the single crystal layer; and
a compound semiconductor layer provided on the single crystal layer via the buffer layer,
wherein the coefficient of thermal expansion of the polycrystalline layer is greater than the coefficient of thermal expansion of the single crystal layer, and is smaller than the coefficient of thermal expansion of the compound semiconductor layer.

13. The semiconductor device according to claim 12, wherein
the single crystal layer includes single crystal silicon, and
the bonding layer includes polycrystalline silicon.

14. The substrate of claim 12, wherein the polycrystalline layer surrounds the single crystal layer.

15. The semiconductor device according to claim 12, wherein
the first single crystal layer comprises single crystal silicon or single crystal sapphire, and
the second single crystal layer comprises single crystal silicon, single crystal sapphire, single crystal silicon carbide, or single crystal gallium nitride.

16. The semiconductor device according to claim 12, wherein the first single crystal layer comprises single crystal silicon or single crystal sapphire.

17. The semiconductor device according to claim 12, wherein the second single crystal layer comprises single crystal silicon, single crystal sapphire, single crystal silicon carbide, or single crystal gallium nitride.
